(19) United States
(12) Patent Application Publication
(10) Pub. No.: US 2025/0035755 A1
(43) Pub. Date: Jan. 30, 2025

(54) OPTOELECTRONIC COMPONENT AND LIDAR SYSTEM

(71) Applicant: ams-OSRAM International GmbH, Regensburg (DE)

(72) Inventors: Hubert HALBRITTER, Dietfurt-Toeging (DE); Simon LANKES, Regensburg (DE); Reiner WINDISCH, Pettendorf (DE)

(21) Appl. No.: 18/717,010

(22) PCT Filed: Nov. 28, 2022
(86) PCT No.: PCT/EP2022/083451

§ 371 Date: Jun. 6, 2024

(30) Foreign Application Priority Data
Dec. 6, 2021 (DE) 102021132010.0

(51) Int. Cl. G01S 7/484; G01S 7/486; G01S 17/48; G01S 17/58; G02B 6/12; G02B 6/43

(52) U.S. Cl. CPC G01S 7/484; G01S 7/486; G01S 17/48; G01S 17/58; G02B 6/12; G02B 6/43; G02B 2006/12121; G02B 2006/12142; G02B 2006/12161

(57) ABSTRACT

The present disclosure provides an optoelectronic component for a LiDAR system including a photonic integrated circuit. The photonic integrated circuit further includes a microresonator which is configured as an external resonator for an optical gain medium and to provide a frequency-modulated optical transmission field. A waveguide is optically coupled to an output side of the microresonator. A coherent in-line balanced detector comprises an electrical output, as well as a first optical connection side which is coupled to the waveguide to receive the transmission field, and a second optical connection side which is configured to receive a frequency-modulated optical reflection field. The coherent in-line balanced detector is further configured to superimpose the transmission field and the reflection field and to provide an electronic combination signal at the electrical output.

### CROSS-REFERENCE TO RELATED APPLICATIONS

This application is a 371 U.S. National Phase of PCT International Patent Application No. PCT/EP2022/083451, filed on Nov. 28, 2022, which claims priority from German Patent Application No. 10 2021 132 010.0, filed on Dec. 6, 2021, the disclosures of which are incorporated by reference herein in their entirety for all purposes.

### TECHNICAL FIELD

The following description relates to an optoelectronic component for a LiDAR system, and a LiDAR system.

### INTRODUCTION

Optical components and optical sensors are used in a wide range of applications in the consumer and automotive sectors. Light Detection and Ranging (LiDAR for short), for example, is a key technology for mobile devices such as cell phones, computers and tablets, and is also increasingly being used in robots and vehicles such as autonomous vehicles. Today's LiDAR systems typically emit short pulses of light at a fixed frequency. The position of objects can be determined by measuring how long it takes for these laser pulses to be reflected or scattered by surfaces and return to the sensor.

The further away an object is, the longer it takes for the light to return. Modern LiDAR systems can also use a constant stream of light (“continuous wave”, cw) and change the frequency of this light at regular intervals (“frequency modulated”, fm). Such FMCW LiDAR (Frequency Modulated Continuous Wave LiDAR) systems can both determine the location of objects and measure their speed using the Doppler effect.

FMCW LiDAR systems today require optical isolators and circulators, among other things, which cannot currently be integrated. This delimits a compact design because further integration is not possible, with the associated additional costs and loss of performance.

It is the object of the present description to propose an optoelectronic component for a LiDAR system and a LiDAR system that enables a more compact design.

These objects are achieved by the subject matter of the independent claims. Further developments and embodiments are described in the dependent claims and will become apparent from the following description and the drawings.

### SUMMARY

It is understood from the following that any feature described in relation to any embodiment may be used alone or in combination with other features described below, and may also be used in combination with one or more features of any other embodiment or any combination of any other embodiment, unless described as an alternative. Furthermore, equivalents and modifications not described below may also be used without departing from the scope of the proposed optoelectronic component for a LiDAR system and the proposed LiDAR system defined in the accompanying claims.

In the following, an improved concept in the field of optical components for LiDAR systems is presented. The proposed concept is based on a photonic integrated circuit that integrates a number of components that enable the use of the optoelectronic component in a LiDAR system. A combination of an optical gain medium and a microresonator forms a laser with an external resonator which results in a small linewidth and high isolation and thus has the function of an optical isolator. Together with a counter-propagating coherent in-line (balanced) detector, a very compact system can be formed in which isolators and circulators can be dispensed with. All of this can be integrated to a large extent or even completely in photonic integrated circuits (PICs).

According to one embodiment, an optoelectronic component for a LiDAR system includes a photonic integrated circuit. The photonic integrated circuit includes a microresonator which is configured as an external resonator for an optical gain medium. Furthermore, the microresonator is configured to provide a frequency-modulated optical transmission field. In addition, a waveguide, in particular a monomode waveguide, is provided which is optically coupled to an output side of the microresonator. Furthermore, a coherent in-line balanced detector having an electrical output and a first and second optical connection side is provided. The first connection side is coupled to the waveguide to receive the transmission field. The second connection side is configured to receive a frequency-modulated optical reflection field. The coherent in-line balanced detector is further configured to superimpose the transmission field and the reflection field and to provide an electronic combination signal at the electrical output. The detector measures the temporal progression of the position of the resulting interferences and provides this information as a detector signal at the electrical output.

The optoelectronic component can be operated in a LiDAR system, for example. More details on the mode of operation are described below in connection with such a LiDAR system. In a sense, the optoelectronic component provides coherent detection for the LiDAR system. The transmission field and the reflection field are superimposed in a counter-propagating manner in the coherent in-line balanced detector, for example mixed according to heterodyne detection. The transmission field can be transmitted to an external object and be detected as the reflection field after reflection or scattering at the external object. The transmission field thus serves as a transmitted field and as a local oscillator.

On the one hand, the coherent in-line balanced detector superimposes the transmission field and the reflection field. For example, the coherent in-line balanced detector can be designed as a balanced optical heterodyne detector. In addition, the coherent in-line balanced detector is configured to detect one or more mixed signals from the coherent superposition of transmission field and reflection field as an electronic combination signal. For example, derived mixed signals can be detected as a differential or sum current. In particular, the distance of an external object that reflects the transmission field as a reflection field can be determined from the electronic combination signal. For example, a difference frequency of transmission field and reflection field can be determined from the electronic combination signal by Fourier transformation, which is proportional to a distance of the external reflecting object. An output usually includes several connections, four in the case of a differential detector, whose signals are combined to form an output signal.

Transmission field and reflection field are manifested by optical wave trains. The transmission field can be generated in particular by stimulated emission. In a LiDAR system, for example, this is done by the microresonator in conjunction with the optical gain medium such as a semiconductor optical amplifier or semiconductor lasers, which form a laser with an external resonator. In addition, the transmission field is frequency modulated and subsequently passes through the coherent in-line balanced detector in one direction. The transmission field can then be coupled out from the optoelectronic component and reflected or scattered at an external object as a reflection field. The reflection field is then coupled back into the optoelectronic component and subsequently passes through the coherent in-line balanced detector in a direction opposite to the transmission field. The measurement is carried out by coherent superposition and measurement of the interference patterns from the transmission field and the reflection field. In other words, both the transmission field and the reflection field propagate through the coherent in-line balanced detector, wherein only a part of the fields is absorbed and propagation takes place in opposite directions.

The optical gain medium includes, for example, a semiconductor optical amplifier (gain chip). The semiconductor optical amplifier can be designed without a resonator so that it does not represent a laser on its own.

Instead, the combination of semiconductor optical amplifier and microresonator forms a laser with an external resonator. Alternatively, the optical gain medium can be designed as a semiconductor laser. For example, the semiconductor laser has a resonator that is partially anti-reflective. For example, an outcoupling mirror of the resonator facing the downstream microresonator is anti-reflective.

The proposed optoelectronic component is particularly suitable for a LiDAR system and has a number of advantages. For example, no optical isolator and no circulator are required. There is also no need for an optical element to replace a circulator. All components (with the possible exception of the laser itself) can be integrated into the photonic integrated circuit (PIC). This results in a smaller space requirement and lower manufacturing costs. It is also possible to integrate several individual systems on one PIC, for example a 1D array for one- or two-dimensional scanning. Furthermore, a higher pixel resolution of the FMCW system is possible.

According to at least one embodiment, a semiconductor optical amplifier (SOA) is connected to a connection side of the coherent in-line balanced detector, in particular to the second connection side, for example by means of a waveguide.

In a LiDAR system, the semiconductor optical amplifier can thus be arranged between the coherent in-line balanced detector and an optical element. Such an amplifier is preferably operated in the linear range, i.e. not in saturation.

A field received by the optoelectronic component, in particular the reflection field, is amplified by the semiconductor optical amplifier before detection by the coherent in-line balanced detector, whereby a higher signal-to-noise ratio can be achieved. The absorbed light component of the coherent in-line balanced detector can thus be set significantly higher than without a semiconductor optical amplifier, as the transmission field is amplified again before emission. This means that a low-power laser is sufficient, and a higher proportion of its transmission field can be absorbed as a local oscillator. The ratio of transmission field and reflection field can be adjusted by selecting the amplification. This setting option can prevent saturation of the detector without delimiting the emitted power.

According to at least one embodiment, the coherent in-line balanced detector has a symmetrical receiver structure. The symmetrical receiver structure is configured to receive and superimpose the transmission field and the reflection field in a counter-propagating manner.

For example, the symmetrical receiver structure is configured such that the transmission field and the reflection field are coupled into the structure on two different connection sides. This allows the optical fields to propagate in opposite directions and interfere, the transmission field and the reflection field being superimposed.

Due to the symmetrical receiver structure, an optical heterodyne detector with two inputs is realized in a sense. The transmission field is normally much larger than the reflection field. The superposition of the transmission and reflection fields produces a beat with an amplitude that is proportional to the geometric mean of the amplitude of the transmission field and the amplitude of the reflection field, which is superimposed on the sum of the individual amplitudes as a DC component. This can be detected as a sum and difference signal. By forming the difference, this DC component is eliminated, while the beat field is doubled due to its phase position. The phase position of the two channels of the detector is selected by the geometric arrangement so that the two signals are shifted by pi. This results in the elimination of the DC component and doubling of the beat component when forming the difference.

According to at least one embodiment, the symmetrical receiver structure has an integer number of electrode pairs. The electrode pairs each include opposing symmetrical electrodes. The pairs of electrodes are arranged relative to each other according to the nodes and anti-nodes of a standing wave field, which is generated as a function of the transmission field and the reflection field at the pairs of electrodes. In this way, the electrode pairs generate the electronic combination signal as a function of the interference of the transmission field and the reflection field.

For example, the laser with the microresonator as an external resonator emits a frequency chirp that leads to a frequency difference between the transmission and reflection fields. This in turn causes the standing wave field to move, causing the measured combination signal to change periodically with the beat frequency as a function of the chirp rate.

For example, the opposing electrodes are each contacted by metal contacts. The standing wave field is generated by the symmetrical receiver structure from the transmission field and the reflection field and detected by the electrode pairs. For example, the electrodes of a pair are each interdigitated, symmetrically arranged electrodes.

Coupling between the standing wave field and the electrodes is achieved, for example, by an absorbing layer into which parts of the transmission and reflection fields are coupled in as evanescent modes. Materials that can be used include Ge, InP and InGaAs, for example for a wavelength range of around 1.5 μm, or additionally Si for a wavelength range below 1.1 μm. In particular, all materials that can be used for 1.5 μm also work in principle. Graphene can also be used as an absorbing material.

According to at least one embodiment, the coherent in-line balanced detector includes at least one pair of photodetectors which are configured to detect at least parts of an evanescent field of the fields guided in the waveguide.

According to at least one embodiment, the symmetrical receiver structure includes a waveguide-integrated standing wave detector. The symmetrical electrodes are arranged in a layer of the standing wave detector.

For example, the standing wave detector has N pairs of electrodes (N unit cells) arranged as a symmetrical receiver structure. A photonic base layer is provided as a waveguide and includes, for example, SOI strip waveguides on an insulator (silicon-on-insulator, SOI). To obtain a planarized surface, the waveguide can be filled with silicon dioxide.

Another thin SiO₂ layer can be deposited on the planarized surface to electrically insulate the layer from the underlying waveguide.

An optical waveguide mode can couple in to the absorbing layer of the symmetrical electrodes through an evanescent field, which can lead to optical absorption and photon-generated charge carriers. The electrode pairs, such as interdigitated symmetrical electrodes, are arranged, for example, on a surface of absorbing material in the region of the strip waveguide. The corresponding electrodes can be contacted with metal contacts (or contact pads), which are arranged on opposite sides, for example.

According to at least one embodiment, the symmetrical electrodes are arranged in a layer of the above-mentioned materials (Ge, InP, InGaAs, Si, Ge, graphene) of the standing wave detector.

According to at least one embodiment, the coherent in-line balanced detector is configured to provide the electronic combination signal at the output as a differential current as a function of the transmission field and the reflection field. The optoelectronic component further includes a transimpedance amplifier which is configured to convert the differential current into an output voltage.

According to at least one embodiment, the photonic integrated circuit further includes a feedback path. The feedback path is configured to provide feedback for controlling or regulating a laser. In a LiDAR system, for example, the laser is formed from the optical gain medium and the microresonator. The control, regulation and/or frequency modulation of the external cavity laser (ECL) is carried out electrically.

The optoelectronic component can be operated with an optical gain medium, for example a semiconductor optical amplifier or semiconductor laser. The optical gain medium forms an external cavity laser using the microresonator as an external resonator. The feedback provides a control or regulation signal for the laser and sets the frequency modulation or a frequency chirp, for example.

According to at least one embodiment, the feedback path is coupled to the microresonator. The feedback path is configured to control or regulate a frequency of the frequency-modulated optical transmission field, wherein the control or regulation of the frequency of the frequency-modulated optical transmission field takes place, for example, by means of a temperature dependency, by means of piezo effects or by means of refractive index modulation. Feedback to the laser or microresonator is provided electrically, for example from a measurement of the modulation frequency. For this purpose, the feedback path includes, for example, amplifiers or intelligent converters, which can be further implemented as ASICs.

According to at least one embodiment, the waveguide structure includes a demodulator for frequency control. In this way, a control signal derived from the frequency-modulated transmission field is used for feedback.

According to at least one embodiment, the photonic integrated circuit includes a plurality of channels. Each channel includes a waveguide and coherent in-line balanced detector according to the proposed concept and/or one or more microresonators. One microresonator may also be provided for several or all channels.

In other words, a microresonator of a channel is configured as an external resonator for an associated optical gain medium and is configured in each case to provide a frequency-modulated optical transmission field of the channel. Furthermore, each channel has a waveguide that is optically coupled to an output side of the associated microresonator. Finally, a coherent in-line balanced detector is provided in each case, which includes an output and a first and second connection side. A first connection side is coupled to the waveguide to receive the transmission field of the channel. The second connection side is configured to receive a frequency-modulated optical reflection field. The coherent in-line balanced detector of the channel is configured to superimpose the transmission field of the channel and the reflection field and to provide an electronic combination signal at the output.

The previous explanations can be understood, for example, as a description of a single channel. The mode of operation and further configurations for an optoelectronic component with a plurality of channels can be applied analogously.

According to at least one embodiment, the photonic integrated circuit includes a plurality of channels. However, the microresonator is optically coupled to several channels, so that one laser (consisting of optical gain medium and microresonator) supplies several or all channels.

According to at least one embodiment, at least one channel includes a microresonator providing an optical transmission field which is detuned in wavelength with respect to one or more of the remaining optical transmission fields of another channel or several other channels. In this way, the channels can be better separated in the application in a LiDAR system and optical crosstalk can be reduced. This allows more reliable detection, for example by avoiding false targets.

According to at least one embodiment, the optoelectronic component includes an optical outcoupling element. The optical outcoupling element is configured to provide the transmission field and configured to receive the reflection field. For example, the semiconductor optical amplifier is arranged between the coherent detector and the optical outcoupling element.

The optical outcoupling element is used to couple the transmission field out from the photonic integrated circuit. If the optoelectronic component is installed in a LiDAR system, the transmission field can be fed to an optical LiDAR element and illuminate a distant object or scan a scene. The transmission field can then be reflected or scattered and detected again by the LiDAR system as a reflection field. The reflection field received in this way can be coupled back into the photonic integrated circuit by the optical outcoupling element and fed to the coherent detector.

According to at least one embodiment, the optical outcoupling element of one channel is tilted relative to the optical outcoupling element of another channel. By tilting the optical outcoupling elements channel by channel, the transmission fields can be coupled out in slightly different directions. In this way, one-dimensional illumination can be achieved on the optoelectronic component side, for example a parallel measurement in a strip geometry. This can be extended to a scanner for a LiDAR system using a movable optical outcoupling element. If the resulting movement is transverse to the main extension of the above-mentioned one-dimensional, strip-like illumination, this combination makes it possible to cover two dimensions.

According to one embodiment, a LiDAR system includes an optoelectronic component according to one or more of the aspects discussed above. Further, the LiDAR system includes an optical element and an optical gain medium with the microresonator as an external resonator.

The optical gain medium completes the microresonator to form an external cavity laser, referred to below as a laser for short. This laser can be pumped electronically or optically, for example, and provides the optical transmission field by means of a laser process, which field is coupled into the waveguide. The frequency of the optical transmission field is modulated. This can be done, for example, by a laser driver, such as a linearly chirped laser.

For example, an FMCW method can be implemented with the LiDAR system. The linearly chirped laser then provides the frequency-modulated optical transmission field. In a sense, the transmission field serves as a local oscillator. In the case of a static target, the received reflection field is a time-delayed version of the transmitted transmission field. By superimposing the transmission field (as a local oscillator) and the received reflection field in the coherent in-line balanced detector (an optical superposition receiver, so to speak), the frequency difference between the transmitted and received fields can be extracted. The frequency difference is proportional to the propagation time and is therefore a measure of the target distance.

According to at least one embodiment, the LiDAR system further includes a laser driver. The laser driver is configured to control the laser in such a way that the frequency-modulated optical transmission field has a specific time-dependent frequency response. In addition or alternatively, the laser driver is configured to control the laser in such a way that the frequency of the frequency-modulated optical field is increased (up-chirped) or reduced (down-chirped) for a period of time.

When the target is moving, the received reflection field has an additional frequency with a frequency shift determined from the Doppler effect, which is proportional to the speed of the target. To measure both the distance and speed to a target, triangular modulation is usually used, where an up-chirp is immediately followed by a down-chirp through the laser driver. The measured frequency differences during the up-chirp or down-chirp can then be used to calculate the distance to the target.

Further advantages and advantageous embodiments as well as further developments of the present description will become apparent from the embodiments described below in conjunction with figures.

In the exemplary embodiments and figures, components that are identical or have the same effect may each be provided with the same reference signs. The elements shown and their proportions to one another are not to be regarded as true to scale; rather, individual elements, such as layers, components, structural elements and areas, may be shown in exaggerated thickness or large dimensions for better visualization and/or better understanding.

### BRIEF DESCRIPTION OF THE DRAWINGS

In the figures:

FIG. 1 shows an exemplary embodiment of an optoelectronic element,

FIG. 2 shows another exemplary embodiment of a LiDAR system with an optoelectronic element,

FIG. 3 shows another exemplary embodiment of a LiDAR system with an optoelectronic element,

FIG. 4 shows another exemplary embodiment of a LiDAR system with an optoelectronic element,

FIG. 5 shows another exemplary embodiment of a LiDAR system with an optoelectronic element,

FIG. 6 shows another exemplary embodiment of a LiDAR system with an optoelectronic element,

FIG. 7 shows another exemplary embodiment of a LiDAR system with an optoelectronic element,

FIGS. 8A-8B show an exemplary embodiment of a coherent in-line balanced detector,

FIG. 9 shows an exemplary embodiment of a standing wave detector,

FIG. 10 shows an exemplary arrangement of the electrodes of a standing wave detector, and

FIGS. 11A-11C show various embodiments of microresonators.

### DETAILED DESCRIPTION

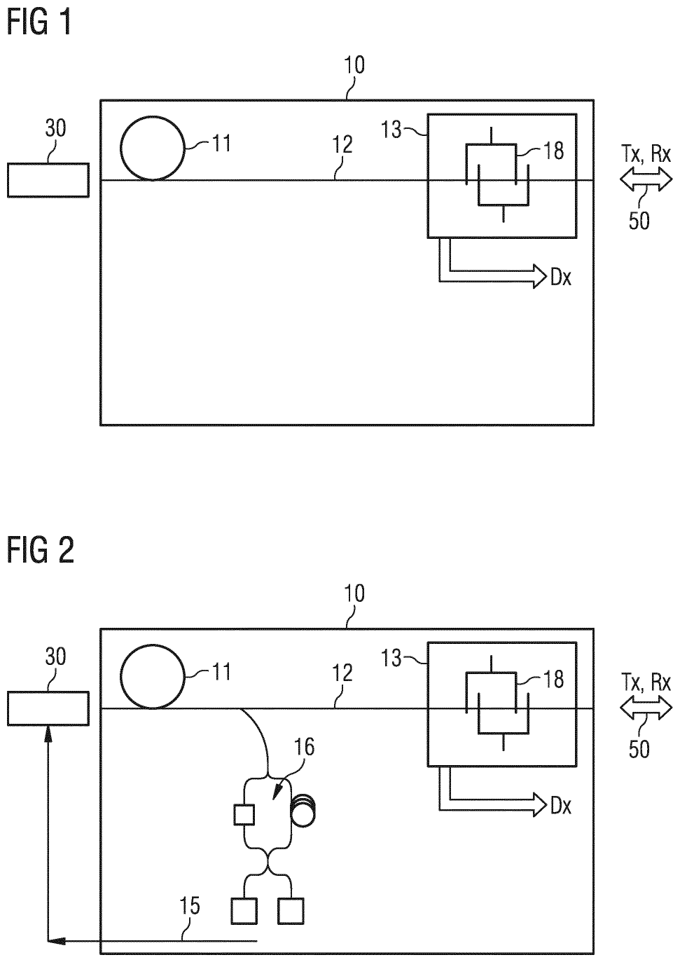

FIG. 1 shows an exemplary embodiment of a LiDAR system with an optoelectronic element. The LiDAR system includes an optoelectronic element with a photonic integrated circuit 10, an optical gain medium 30 and an optical (LiDAR) element 50. The photonic integrated circuit 10 includes a microresonator 11, a waveguide 12 and a coherent in-line balanced detector 13.

Together with the microresonator 11, the optical gain medium 30 forms an external cavity laser (ECL) and has a high level of optical isolation. The microresonator 11 is part of the external resonator for the optical gain medium 30. The optical gain medium together with the external resonator is referred to in the following as “laser” for short. The optical gain medium 30 is generally not integrated on the photonic integrated circuit 10, but can also be integrated into it in whole or in part.

The optical gain medium 30 is, for example, a semiconductor laser, such as a VCSEL, an edge emitting laser or a gain chip with an anti-reflective coating on an outcoupling facet. The resonator of the semiconductor laser is completely or partially anti-reflective so that generated radiation can be coupled out into the microresonator and an external laser resonator can be formed with the microresonator. Alternatively, the optical gain medium includes a semiconductor optical amplifier.

The microresonator 11 includes an output side that is optically coupled to the waveguide 12. The laser process generates an optical transmission field Tx by means of the microresonator and couples it in to the waveguide. The laser and/or the microresonator can be controlled and operated by a laser driver. For example, the laser driver can perform frequency modulation so that the optical transmission field Tx is modulated with a frequency. For example, the laser is linearly chirped.

The waveguide 12 is also coupled to a first connection side of the coherent in-line balanced detector 13 and is configured to couple in the transmission field Tx into the coherent detector. The coherent detector 13 also includes a second connection side. At this connection side, the transmission field Tx can be coupled out of the coherent in-line balanced detector and fed to the optical (LiDAR) element 50 in order to be transmitted from there. For example, the optical element 50 can be moved in the manner of a scanner and includes a MEMS element, for example. An optical outcoupling element 14 is coupled to the second connection side of the coherent in-line balanced detector via the waveguide 12.

The second connection side is also configured to couple in a reflection field Rx into the detector. This reflection field can be received by the LiDAR system, for example. The transmission field transmitted into a scene or to an external object thus becomes the reflection field through reflection and/or scattering. Since the reflection field Rx is propagated to a target and back, it is mathematically idealized as a time-delayed waveform as a replica of the waveform of the transmitted transmission field Tx.

The coherent in-line balanced detector 13 includes a symmetrical receiver structure that is configured to receive the transmission field Tx and the reflection field Rx in a counter-propagating manner at the two optical connection sides of the detector. The symmetrical receiver structure superimposes the two fields Tx and Rx interferometrically and generates an electronic combination signal Dx, which is provided at the output of the detector. The symmetrical receiver structure has an integer number of electrode pairs for this purpose, the electrode pairs comprising, for example, opposing, symmetrical electrodes. As is further explained in FIG. 6, these are arranged, for example, in an absorbing layer of a standing wave detector. The electrode pairs are arranged relative to one another in such a way that they essentially come to lie at nodes and anti-nodes of a standing wave field generated from the transmission field Tx and reflection field Rx. The electrode pairs detect this standing wave field as the electronic combination signal Dx. The electronic combination signal Dx is, for example, a differential current. The optoelectronic component may further include a transimpedance amplifier that converts the differential current into an output voltage Vout.

During operation, light from the frequency-controlled or “chirped” laser is generated and transmitted to an external target as a frequency-modulated optical transmission field Tx. The laser light returning from the target is interferometrically recombined with the transmission field Tx as a reflection field Rx and detected. The transmission field serves both as a local oscillator and as a transmitted field. Due to the propagation time of the reflection field, this has a time delay of

$${τ}_{D} = \frac{2 R}{c} ,$$

where R is the distance to the point of reflection/scattering (or external target) and c is the speed of light.

For example, the coherent in-line balanced detector 13 measures the heterodyne beat frequency (difference frequency) between the two optical fields that determine the standing wave field consisting of the reflection field and the transmission field. The heterodyne beat frequency is given by

$${f}_{beat} = {κτ}_{D} ,$$

where κ denotes the chirp rate of the laser. The distance R can be extracted from a field processing of the electronic combination signal Dx, for example from a Fourier transformation:

$$R = \frac{{f}_{beat} c}{2 κ}$$

The LiDAR system does not require an optical isolator or a circulator. There is also no need for an additional optical element to separate the transmission and reflection fields to replace a circulator. In particular, an isolating function is implemented because the reflection field has a frequency shift compared to the transmission field and thus compared to the resonance of the microresonator. In this way, the returning field is not coupled back into the laser. All components (with the possible exception of the optical gain medium) are integrated into the photonic integrated circuit (PIC). This results in a smaller space requirement and lower manufacturing costs. It is also possible to integrate several individual systems on one PIC, for example a 1D array for one- or two-dimensional scanning. Furthermore, a higher pixel resolution of the FMCW system is possible.

The LiDAR system can include other components that are used, for example, for control, signal processing and activation by external devices or components. This can include, for example, a microcontroller, a logic, interfaces or other components. These other components can also be integrated on the photonic integrated circuit, for example.

FIG. 2 shows another exemplary embodiment of a LiDAR system with an optoelectronic element. The system shown here is based on the system already shown in FIG. 1. In addition, the photonic integrated circuit includes a feedback path. This feedback path leads to the optical gain medium 30 and implements a feedback loop that is used to control the laser. In this example, the feedback path includes a demodulator 16, in particular an FM-AM demodulator for chirp control. The demodulator can be realized, for example, on the basis of a Mach-Zehnder interferometer. Based on the transmission field Tx, the demodulator provides a feedback signal, which is fed back to a laser driver (not shown) to control or regulate the laser or gain chip.

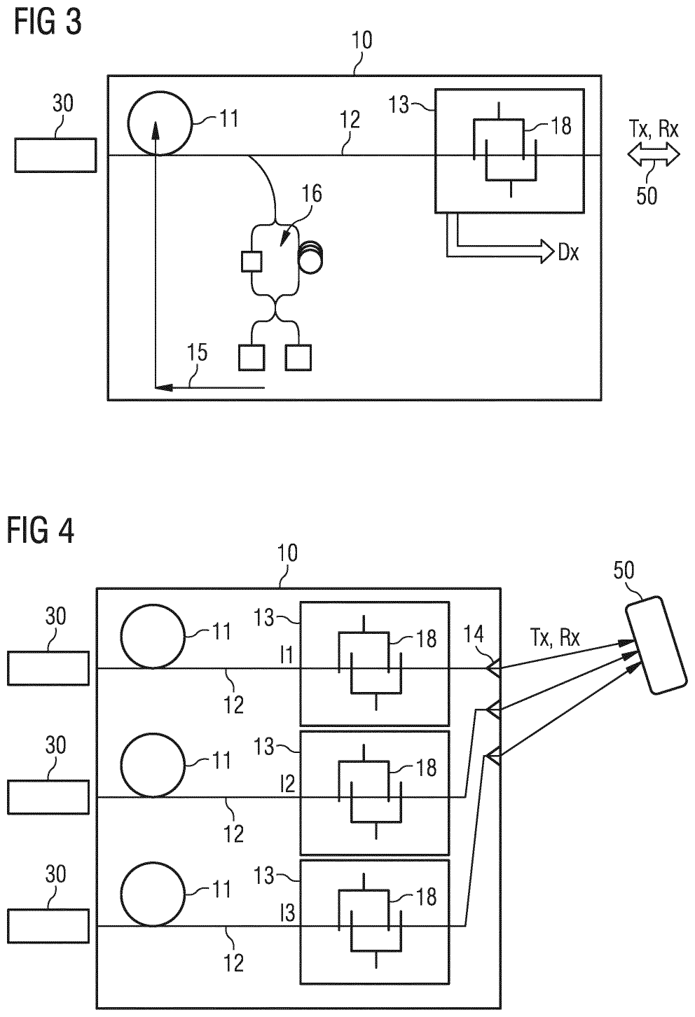

FIG. 3 shows another exemplary embodiment of a LiDAR system with an optoelectronic element. This embodiment is similar to that shown in FIG. 2 and again includes the feedback path 15 and demodulator 16. In this case, however, the feedback path is coupled back to the microresonator 11. Based on the transmission field Tx, the demodulator provides a feedback signal, which is used to control the microresonator for chirp control (control/regulation of the chirp), for example thermally or by means of the piezo effect or via refractive index modulation within the waveguide structure of the feedback path).

FIG. 4 shows another exemplary embodiment of a LiDAR system with an optoelectronic element. In this embodiment, different channels are implemented on the photonic integrated circuit, each comprising a microresonator 11, a waveguide 12 and a coherent in-line balanced detector 13. Each channel also includes an optical gain medium 30. The mode of operation and further configurations are analogous to the previous description of a photonic integrated circuit with only one channel. The channels are each coupled to an optical (LiDAR) element 50 via an optical outcoupling element 14 (e.g. a phononic grating). The outcoupling can, for example, be in slightly different directions for each channel, which effectively implements a parallel measurement in a strip geometry. Combined with a 1-D scanner (e.g. optical element 50) and a scanning direction transverse to the main extension of the strip geometry, it is possible to cover two dimensions.

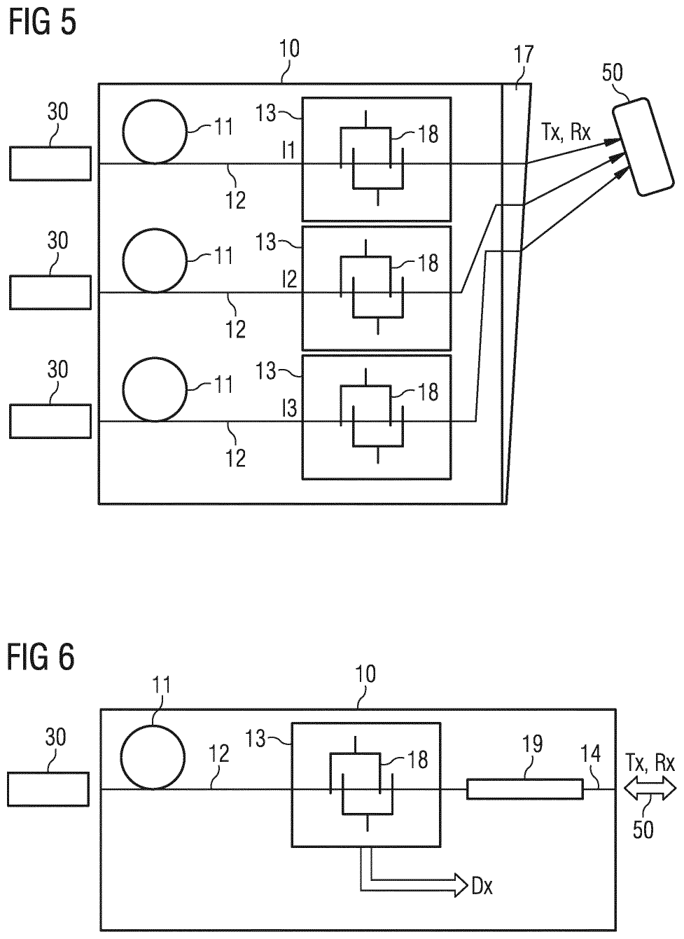

FIG. 5 shows another exemplary embodiment of a LiDAR system with an optoelectronic element. This embodiment is similar to that shown in FIG. 4 and again includes different channels. In this example, the microresonators have a detuned wavelength compared to the other microresonators. Furthermore, the photonic integrated circuit may have a prismatic waveguide structure 17 to form a strip geometry. This prismatic waveguide structure leads to a slightly “tilted” strip geometry, as the wavelengths are refracted differently. This implementation can, for example, be combined with an optical (LiDAR) element 50 (e.g. based on MEMS) to create a 2D scanner.

FIG. 6 shows another exemplary embodiment of a LiDAR system with an optoelectronic element. In contrast to the example in FIG. 1, a semiconductor optical amplifier 19 is also provided. The semiconductor optical amplifier (SOA) is arranged between the coherent in-line balanced detector 13 and an optical element. The amplifier is operated in the linear range and is therefore not saturated.

During operation, the transmitted field Tx is amplified by the semiconductor laser amplifier 19 and the reflected field Rx is received. The field is amplified by the semiconductor laser amplifier 19 before detection by the coherent in-line balanced detector 13, whereby a higher signal-to-noise ratio can be achieved. The absorbed light component of the coherent in-line balanced detector can thus be set significantly higher than without an amplifier (as in FIG. 1, for example) as the transmitted laser light is amplified again before emission. This means that a low-power laser is sufficient, and a higher proportion of its emission can be absorbed as a local oscillator. The ratio of local oscillator, as the transmission field and reflection field can be set by selecting the amplification. This setting option can be used, for example, to prevent saturation of the detector without delimiting the emitted power.

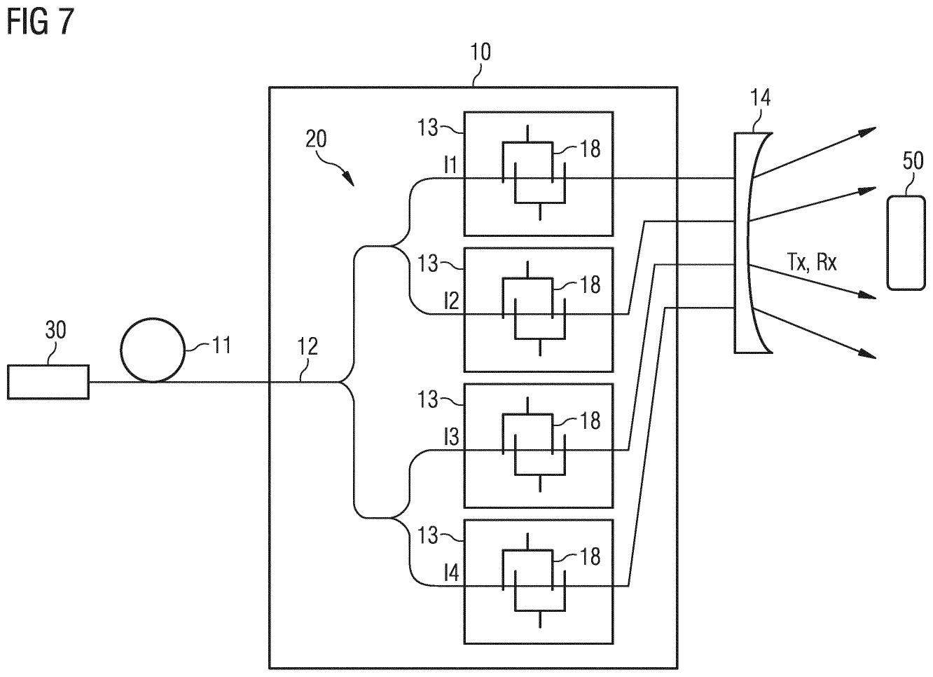

FIG. 7 shows another exemplary embodiment of a LiDAR system with an optoelectronic element. This embodiment includes various channels 11, . . . , 14 as described in FIGS. 4 and 5. However, only one optical gain medium 30 and one microresonator 11 are provided. The waveguide 12 is split several times, so that in each case one path optically connects the optical gain medium 30 with one channel each. The paths can also be switched by means of a switching network 20. The optical outcoupling element 14 has, for example, a lens, such as a plano-concave lens.

During operation, the transmission field generated by the laser can be coupled into the paths and thus propagate through the individual channels. The switching network 20 can be used to create a switching sequence that activates the channels one after the other. In this way, a 1D scan can be implemented for the LiDAR system. The 1D scan can also be extended for different orientations using a suitable scanning optical outcoupling element.

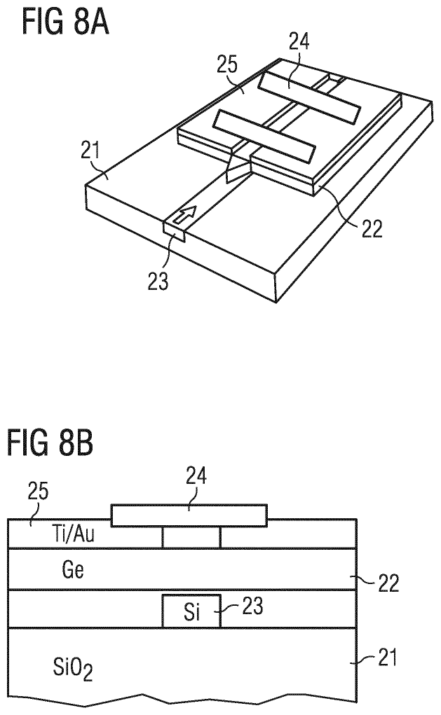

FIGS. 8A-8B show an exemplary embodiment of a coherent in-line balanced detector. This detector includes a symmetrical receiver structure or a waveguide-integrated standing wave detector. The symmetrical receiver structure is arranged on a carrier 21 (here made of SiO₂). The standing wave detector is based on a detector 22 (here a Ge detector) arranged on the carrier 21 and along a waveguide core 23 (here made of Si). The detector 22 includes pairs of symmetrical electrodes 24 (balanced electrodes) for self-balanced detection.

Furthermore, the detector is contacted by means of metal contacts 25 arranged on a surface of the detector.

Electrodes 24 are placed, for example, according to the nodes and anti-nodes of a standing wave pattern that results from the transmission field and reflection field when these travel through the waveguide core 23 (see FIG. 7). The standing wave field generated in this way couples in to the detector 22 through an evanescent field. The pairs of symmetrical electrodes are contacted by the metal contacts 25. An output current of the standing wave detector is thus present at these contacts and represents, for example, a differential current between the photocurrent from the anti-nodes and from the nodes.

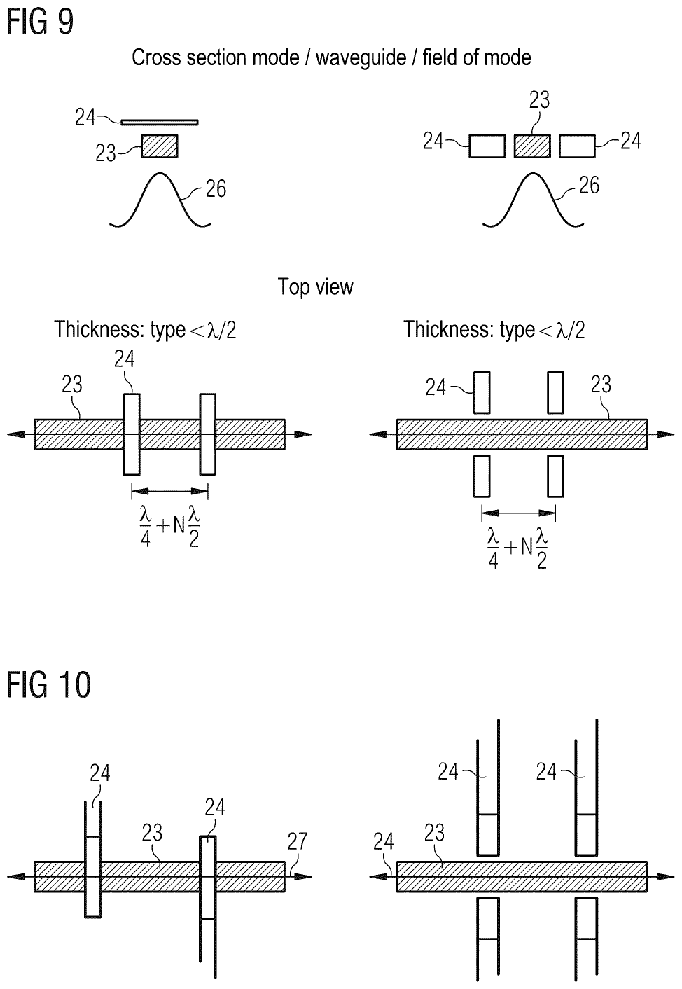

FIG. 9 shows an exemplary embodiment of a standing wave detector. The detector 22 can be designed in different ways, for example with different arrangements of the electrodes and different materials. For example, Ge, InP, and InGaAs can be used as absorbing materials, for example for a wavelength range of about 1.5 μm, or Si or Ge for a wavelength range below 1.1 μm. Graphene can also be used as an absorbing material. The detector can be implemented using metal-semiconductor-metal (MSM), pin or PD structures.

The figure shows various arrangements of electrodes 24 with respect to the waveguide core 23 (in a side view at the top and in a top view at the bottom) and a mode 26.

The left-hand part of the figure shows an arrangement of the electrodes above the plane of the waveguide core 23. A thickness of the electrodes is, for example, less than λ/2, where λ denotes the main laser wavelength. A distance between electrodes is λ/4+Nλ/2, where N is a natural number.

The right-hand part of the figure shows an arrangement of the electrodes next to or parallel to the waveguide core 23, resulting in pairs of opposing electrodes. A thickness of the electrodes is, for example, less than λ/2, where λ denotes the main laser wavelength. A distance between electrodes is λ/4+Nλ/2, where N is a natural number.

FIG. 10 shows an exemplary arrangement of the electrodes of a standing wave detector. The right-hand side shows the arrangement of electrodes next to or parallel to the waveguide core 23, with an additional direction of propagation 27 of the modes being entered. The left-hand side is similar to the example in FIG. 7 with an arrangement of the electrodes above the plane of the waveguide core 23. Here, the electrodes are additionally offset to the direction of propagation 27.

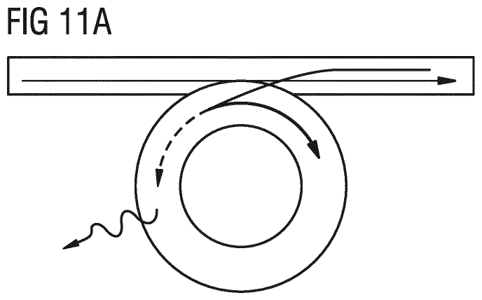

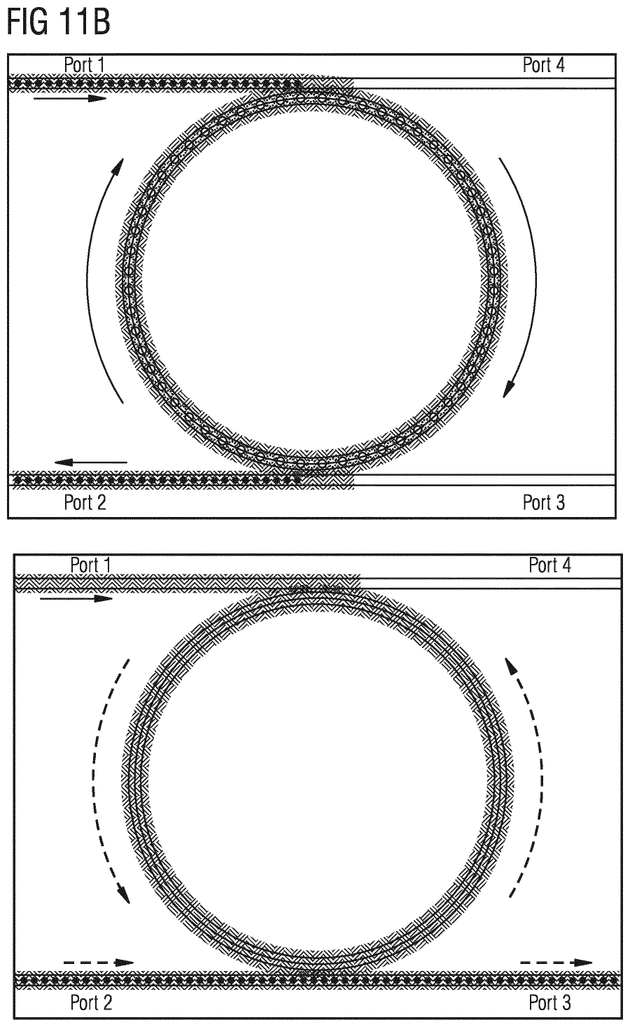

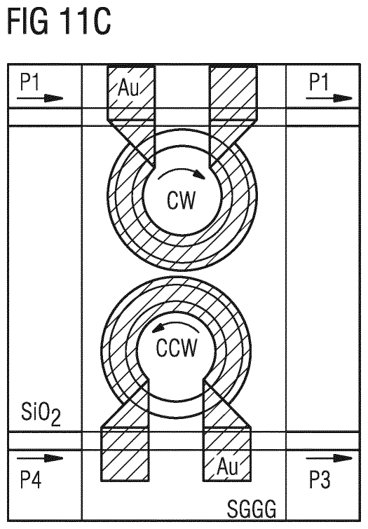

FIGS. 11A-11C show various embodiments of microresonators. Examples include a ring resonator (see FIG. 11A) with two or more contiguous rings. For example, the total closed path length of the reflected light corresponds to an integer multiple of half the laser wavelength. A ring resonator can be configured such that it can be used alternately clockwise and counterclockwise (see FIG. 11B). The ring resonator can also have several contiguous rings (see FIG. 11C).

The microresonators are designed as ring resonators, for example. Together with the laser, a resonance with a very high Q factor is created, which results in a narrow linewidth of the single-mode laser emission. In addition, the microresonators or micro ring resonators serve as optical isolators for the laser and are part of the laser resonator. Therefore, no additional optical isolator is required, which cannot be integrated into the PIC as a bulky external component.

The use of a laser or amplification element (e.g. gain chip) in combination with a microresonator produces a laser element with a narrow linewidth that does not require an optical isolator. In combination with a counter-propagating coherent detector, in particular based on the symmetrical receiver structure shown, a LiDAR system can be integrated in large parts or completely into an integrated photonic circuit without the need for further “hybrid” connection components.

The foregoing description explains many features in specific detail. These are not intended to be construed as limitations on the scope of the improved concept or what can be claimed, but rather as exemplary descriptions of features that are specific only to certain embodiments of the improved concept. Certain features described in this description in connection with individual embodiments may also be realized in combination in a single embodiment. Conversely, various features described in connection with a single embodiment may also be implemented in multiple embodiments separately or in any suitable sub-combination. Moreover, although features are described above as acting together in certain combinations and even originally claimed as such, one or more features from a claimed combination may in some cases be excluded from the combination, and the claimed combination may be directed to a sub-combination or variation of a sub-combination.

Although the drawings show operations in a particular order, this should not be taken to mean that these operations must be carried out in the order shown or in sequential order, or that all the operations shown must be carried out to achieve the desired results. In certain circumstances, different sequences or parallel processing may be advantageous.

A number of implementations have been described. Nevertheless, various modifications can be made without departing from the spirit and scope of the improved concept. Accordingly, other implementations also fall within the scope of the claims.

### REFERENCES

10 photonic integrated circuit
11 microresonator
12 waveguide
13 coherent in-line balanced detector
14 optical outcoupling element
15 feedback path
16 demodulator
17 prismatic waveguide structure
18 symmetrical receiver structure
19 semiconductor optical amplifier
20 switching network
21 carrier
22 detector
23 waveguide core
24 electrode
25 metal contact
26 mode
27 direction of propagation
20 symmetrical electrodes
30 optical gain medium
50 optical (LiDAR) element
11 channel
12 channel
13 channel
14 channel

1. An optoelectronic component for a LiDAR system, comprising a photonic integrated circuit, the photonic integrated circuit comprising:
a microresonator configured as an external resonator for an optical gain medium and to provide a frequency-modulated optical transmission field; and
a waveguide optically coupled to an output of the microresonator; and
a coherent in-line balanced detector comprising an electrical output, as well as a first optical connection side which is coupled to the waveguide to receive the transmission field, and a second connection side which is configured to receive a frequency-modulated optical reflection field, wherein the coherent in-line balanced detector is further configured to superimpose the transmission field and the reflection field and to provide an electronic combination signal at the electrical output.

2. The optoelectronic component according to claim 1, further comprising a semiconductor optical amplifier which is connected to an optical connection side of the coherent in-line balanced detector, in particular to the second connection side of the coherent in-line balanced detector.

3. The optoelectronic component according to claim 1, wherein the coherent in-line balanced detector has a symmetrical receiver structure which is configured to receive and superimpose the transmission field and the reflection field in a counter-propagating manner.

4. The optoelectronic component according to claim 3, wherein
the symmetrical receiver structure has an integer number of electrode pairs,
the electrode pairs each have opposing electrodes, and
a standing wave field with nodes and anti-nodes is generated by the superposition of the transmission field and the reflection field, wherein the electrode pairs are arranged in relation to one another corresponding to the nodes and anti-nodes in such a way that the electronic combination signal is generated by means of the electrode pairs as a function of the difference or sum of the transmission field and the reflection field.

5. The optoelectronic component according to claim 3, wherein
the symmetrical receiver structure comprises a waveguide-integrated standing wave detector, and
the electrodes are arranged in a layer of the standing wave detector.

6. The optoelectronic component according to claim 1, wherein:
the coherent in-line balanced detector is configured to provide the electronic combination signal at the electrical output as a differential current as a function of the transmission field and the reflection field, and
the optoelectronic component further comprises a transimpedance amplifier configured to convert the differential current into an output voltage.

7. The optoelectronic component according to claim 1, wherein the photonic integrated circuit further comprises a feedback path configured to provide feedback for controlling or regulating the optical gain medium and/or the microresonator.

8. The optoelectronic component according to claim 7, wherein
the feedback path is configured to control or regulate a frequency of the frequency-modulated optical transmission field.

9. The optoelectronic component according to claim 7, wherein the feedback path comprises a demodulator for frequency control.

10. The optoelectronic component according to claim 1, wherein a plurality of channels are formed in the photonic integrated circuit, and each channel comprises an arrangement with a microresonator, a waveguide and a coherent in-line balanced detector.

11. The optoelectronic component according to claim 10, wherein at least one channel comprises a microresonator providing an optical transmission field which is detuned in wavelength with respect to an optical transmission field of another channel.

12. The optoelectronic component according to claim 1, wherein a plurality of channels are formed in the photonic integrated circuit, and each channel comprises an arrangement with a waveguide and a coherent in-line balanced detector, wherein the waveguides of several channels are each coupled to the output of the microresonator.

13. The optoelectronic component according to claim 10, further comprising an optical outcoupling element configured to provide the transmission field and/or configured to receive the reflection field.

14. The optoelectronic component according to claim 13, wherein the optical outcoupling element of one channel is tilted relative to the optical outcoupling element of another channel.

15. A LiDAR system, comprising:
an optoelectronic component according to claim 1,
an optical element, and
a laser comprising an optical gain medium, wherein the microresonator or the microresonators form an external resonator or external resonators of the laser.

16. The LiDAR system according to claim 15, further comprising a laser driver which is configured
to control the laser in such a way that the frequency-modulated optical transmission field has a specific time-dependent frequency response, and/or
to control the laser in such a way that the frequency of the frequency-modulated optical transmission field is increased or reduced for a certain period of time.

17. The LiDAR system according to claim 16, wherein the laser driver is integrated in the photonic integrated circuit.

18. The LiDAR system according to claim 15, wherein the LiDAR system is free of optical isolators and/or circulators.
